(19) United States
(12) Patent Application Publication
(10) Pub. No.: US 2010/0216262 A1
(43) Pub. Date: Aug. 26, 2010

(54) METHOD FOR PRODUCING BONDED WAFER

(75) Inventor: Kunihito HARADA, Tokyo (JP)

Correspondence Address: FOLEY AND LARDNER LLP;SUITE 500, 3000 K STREET NW, WASHINGTON, DC, 20007, US

(73) Assignee: COVALENT MATERIALS CORPORATION

(21) Appl. No.: 12/510,549

(22) Filed: Jul. 28, 2009

(30) Foreign Application Priority Data
Feb. 20, 2009 (JP) 2009-037308

(51) Int. Cl. H01L 21/66

(52) U.S. Cl. 438/16; 257/E21.53

(57) ABSTRACT

Bonded wafers are produced by a method including a step (S1) of bonding together a wafer for supporting and a wafer for active layer, thereby forming a bonded body, a step (S2) of fabricating the wafer for active layer of the bonded body, thereby forming the active layer having a first thickness, a step (S3) of sticking a plurality of the bonded bodies having the active layer formed thereon to a polishing plate and polishing the active layer down to a second thickness, a step (S4) of optically measuring the second thickness while keeping the polished bonded bodies stuck to the polishing plate, and a step (S5) of polishing again the active layer down to a third thickness in response to the second thickness measured previously.

### BACKGROUND OF THE INVENTION

1. Field of the Invention

The present invention relates to a method of producing a bonded wafer. More particularly, the present invention relates to a method of producing a bonded wafer, the method being economical and highly productive and easily forming the active layer with an adequate thickness conforming to standards.

2. Description of the Related Art

A bonded wafer includes a base wafer of single crystal silicon and a wafer for an active layer, which are bonded together directly or indirectly with an insulating film interposed between them. It requires the active layer to have an adequate thickness conforming to standards.

There is known a method for meeting this requirement, which has measuring by light interference the thickness of that part of an SOI wafer which overreaches during polishing and controlling in real time the polishing load in response to the measured value. (See Japanese Patent Laid-open No. 8-216016, for example.)

There is known another method which has directing a probe light beam toward the reverse side of a semiconductor wafer being ground, analyzing the spectrum of reflected light by means of a spectrometer, calculating the thickness according to the waveform of the spectrum, and suspending polishing when the desired thickness has been obtained. (See Japanese Patent Laid-open No. 2005-19920, for example.)

### SUMMARY OF THE INVENTION

The above-mentioned related arts are concerned with the technology of single wafer polishing which produces a bonded wafer having an active layer of adequate thickness. Single wafer polishing, however, is less economical and productive than batch polishing to process more than one wafer at one time.

By contrast, batch polishing permits more than one wafer, which are stuck onto a plate with an adhesive, to be polished at one time by means of a polishing cloth being pressed against them. Therefore, it presents difficulties in measuring the wafer thickness during polishing.

In fact, batch polishing needs an additional step to see if the active layer has reached a desired thickness conforming to standards. The additional step involves peeling the wafer from the plate and cleaning the wafer to remove the adhesive etc. before thickness measurement. Until a desired thickness is attained, it is necessary to repeat polishing by sticking the wafer to the plate again. This procedure is troublesome.

The most efficient way is to attain a desired thickness for the active layer unwittingly without examining the active layer for thickness at all during polishing. However, this is not realistic because some of recent products need tolerances as small as ±1.0 μm for the thickness of the active layer. Meeting this need requires the existing polishing equipment to have a new control system capable of accurate control of polishing rate, which is troublesome and uneconomical.

It is an object of the present invention to provide a method for producing bonded wafers, which is capable of easily controlling the thickness of the active layer economically and efficiently without requiring complicated polishing operation.

The present invention achieves the above-mentioned object and is directed to a method for production of bonded wafers which includes a step of bonding together a wafer for supporting and a wafer for active layer, thereby forming bonded bodies, a step of fabricating the wafer for active layer of the bonded bodies, thereby forming the active layer having a first thickness, a step of sticking the bonded bodies having the active layer formed thereon to a polishing plate and polishing the active layer down to a second thickness, a step of optically measuring the second thickness while keeping the polished bonded bodies stuck to the polishing plate, and a step of polishing again the active layer down to a third thickness in response to the second thickness measured previously.

The above-mentioned procedure allows the active layer to have a desired thickness conforming to standards in an economical and efficient way without requiring complicated polishing operation.

The second thickness to be measured in the foregoing procedure should preferably be an average value of thickness at the center of the bonded bodies stuck to the polishing plate.

Measurement in this manner permits easy control of the thickness at the center of the active layer of all the bonded bodies stuck to the same polishing plate.

Moreover, the second thickness to be measured in the foregoing procedure should preferably be an average value of thickness within a plane including the center and the periphery of the bonded bodies stuck to the polishing plate.

Measurement in this manner permits easy control of the thickness within the entire plane of the active layer of all the bonded bodies stuck to the same polishing plate.

Thus, the present invention provides a method for production of bonded wafers which is capable of easily controlling the thickness of the active layer economically and efficiently without requiring complicated polishing operation.

### BRIEF DESCRIPTION OF THE DRAWINGS

Embodiments of the present invention will be described in detail based on the following figures, wherein:

FIG. 1 is a flowchart showing the method for production of bonded wafers according to an embodiment of the present invention;

FIG. 2 is a schematic diagram showing one example of the polishing machine used for the first and second polishing steps (S3 and S5) according to the embodiment of the present invention;

FIG. 3 is a top view showing how a plurality of bonded bodies are stuck to the polishing plate as one example;

FIG. 4 is a schematic diagram showing one example of the apparatus for optically measuring the thickness of the active layer in the step S4 according to the embodiment of the present invention;

FIG. 5 is a top view showing one example of the placement of measuring points for the second thickness, with the bonded bodies stuck to the polishing plate;

FIG. 6 is a top view showing one example of the placement of measuring in-plane points for the second thickness, with the bonded bodies stuck to the polishing plate; and

FIG. 7 is a flowchart for production of bonded wafers according to the embodiment of the present invention.

### DESCRIPTION OF THE PREFERRED EMBODIMENTS

Described below are the preferred embodiments of the present invention in reference to the accompanying drawings.

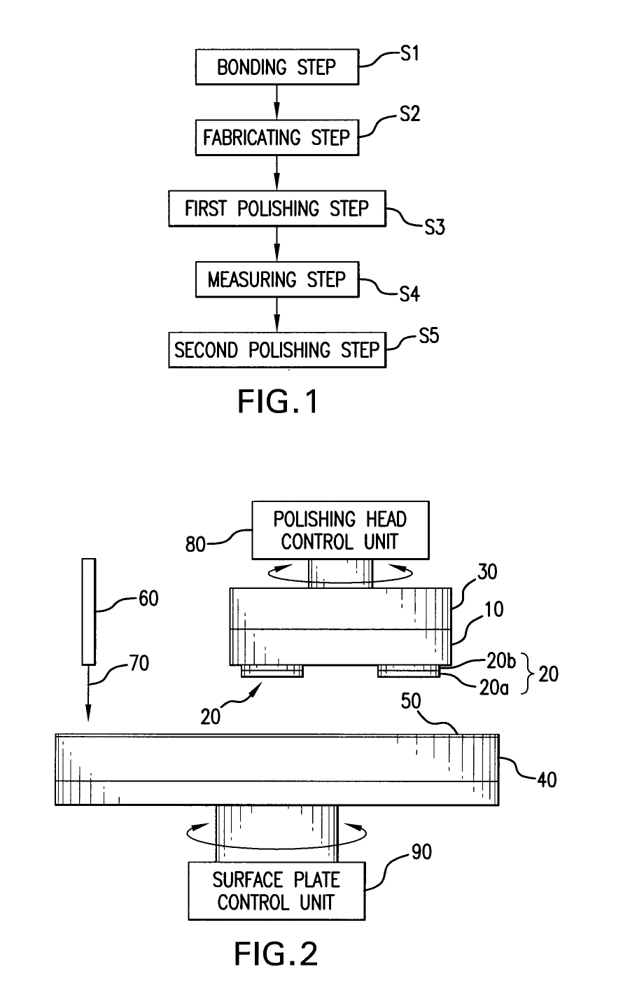

FIG. 1 is a flowchart involved in the method for production of bonded wafers according to an embodiment of the present invention.

As shown in FIG. 1, the method for production of bonded wafers according to the embodiment of the present invention includes a first step (S1) for bonding, a second step (S2) for fabrication, a third step (S3) for first polishing, a fourth step (S4) for measurement, and a fifth step (S5) for second polishing.

The bonding step (S1) is intended to bond together a wafer for supporting and a wafer for the active layer, thereby forming a single bonded body, the former being that of silicon single crystal which has a diameter of 5 inches (125 mm) and a thickness of 600 to 800 μm, and the latter being that of silicon single crystal which has a diameter of 5 inches (125 mm) and a thickness of 600 to 800 μm and also has a controlled oxygen concentration and resistance value.

Any known method may be employed to bond together a wafer for supporting and a wafer for the active layer. Firm bonding will be achieved by placing a wafer for supporting and a wafer for the active on top of the other, with their mirror-finished surfaces facing each other, and performing heat treatment on them at a high temperature (say, 1100° C.)

The fabricating step (S2) is intended to grind the periphery of the bonded body obtained in the boding step (S1) so as to remove the peripheral part which is not bonded. Grinding will reduce the diameter of the bonded body from 5 inches to 4 inches, for example. This step proceeds to grind the wafer for the active layer (which is one surface of the bonded body) so that its thickness decreases to the first thickness.

Incidentally, the first thickness denotes the central value of the standard specifying the thickness of the active layer plus the allowance for polishing in the first and second polishing steps (S3 and S5) to be mentioned later. For example, the central value is 6.0 μm if the standard ranges from 5.0 to 7.0 μm. In this case, the first thickness will be about 20 to 25 μm.

The first polishing step (S3) is intended to stick more than one bonded body, which has the active layer formed thereon by the fabricating step (S2), to the polishing plate with an adhesive and then polish the active layer down to the second thickness.

Incidentally, the second thickness denotes the central value of the standard specifying the thickness of the active layer plus the allowance for polishing in the second polishing step (S5) to be mentioned later. For example, it will be about 10 to 12 μm if the central value of the standard is 6.0 μm.

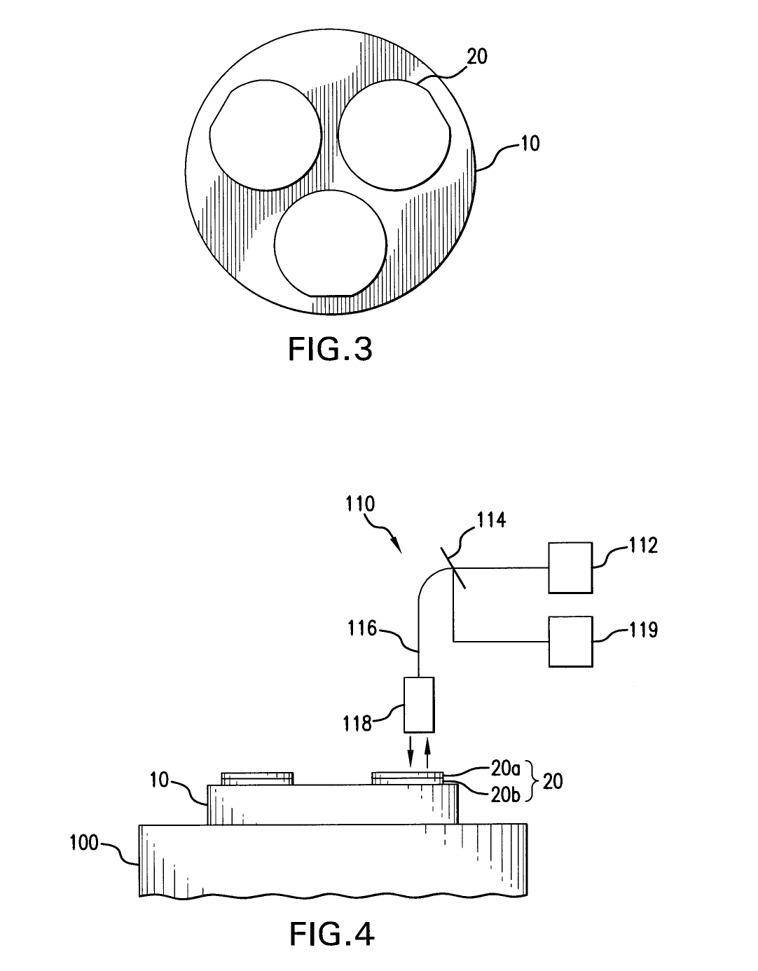

FIG. 2 is a schematic diagram showing one example of the polishing machine used for the first and second polishing steps (S3 and S5) according to the embodiment of the present invention. FIG. 3 is a top view showing how a plurality of bonded bodies are stuck to the polishing plate as one example.

In the first and second polishing steps (S3 and S5) as shown in FIGS. 2 and 3, a plurality of bonded body 20 are stuck to the surface of the polishing plate 10 (which is an alumina plate) with an adhesive such that the active layer 20a of the bonded body 20 faces the polishing surface and the supporting side 20b faces the adhesion surface. The polishing plate 10 is fastened to the polishing head 30. The polishing head 30 is lowered while the polishing cloth 50 placed on the surface plate 40 is being supplied with abrasive 70 from a nozzle 60. Then the polishing head 30 is lowered further so that the active layer 20a of the bonded body 20 is pressed against the polishing cloth 50, during which the polishing head 30 and the surface plate 40 are turned in the same direction or opposite direction.

The active layer 20a is polished at a controlled polishing rate (which is the amount of polishing per unit time of polishing). This is accomplished by the control unit 80 of the polishing head 30 which adjusts the number of revolution of the polishing head 30 and the load on the polishing cloth 50, and also by the control unit of the surface plate 90 which adjusts the number of revolution of the surface plate 40 and the flow rate and kind of the abrasive 70. Any known method is used for such adjustment.

The measuring step (S4) is intended to optically measure the second thickness of the active layer, with the bonded body, which has been polished in the first polishing step (S3), remaining stuck to the polishing plate.

FIG. 4 is a schematic diagram showing one example of the apparatus for optically measuring the thickness of the active layer in the measuring step (S4) according to the embodiment of the present invention.

As shown in FIG. 4, the thickness measurement of the active layer 20a of the bonded body 20 is accomplished by controlling the measuring system 110, with the polishing plate 10, to which the polished body 20 is stuck, placed almost horizontally on the X-Y stage 100 of stainless steel. The measuring system 110 has a light source 112, a half mirror 114, an optical fiber 116, a measuring head 118, and a spectroscope 119. The light source 112 emits infrared light which irradiates the bonded body through the half mirror 114, the optical fiber 116, and the measuring head 118. The infrared light is reflected back by the surface of the bonded body 20 and the bond interface between the active layer 20a and the support 20b. The reflected light passes through the optical fiber 116 and the half mirror 114 and reaches the spectroscope 119, by which it is analyzed. In this way the thickness of the active layer 20a is calculated. The foregoing measuring system 110 may be any known one such as FT-IR.

The second polishing step (S5) is intended to polish the active layer again until the third thickness is attained in response to the second thickness measured in the measuring step (S4). This is accomplished by the method shown in FIGS. 2 and 3.

The third thickness denotes the thickness of the active layer within the standard, preferably the central value of the standard.

According to the embodiment of the present invention, the method for production of the bonded wafer includes the above-mentioned steps. Therefore, it obviates the necessity of temporarily removing the wafer from the polishing plate to measure the thickness of the active layer at the time of batch polishing. This avoids complicated polishing operation. It also obviates the necessity of adding a new control system to the existing polishing apparatus to achieve accurate control of polishing rate. This contributes to cost saving. In addition, the batchwise polishing is highly productive. The foregoing method easily achieves the desired thickness of the active layer as specified by the standard because it includes steps of tentatively polishing the active layer of the bonded body, measuring the thickness of the active layer, and polishing again the active layer until the desired thickness is attained in response to the result of measurement.

The second thickness to be measured by the foregoing step should preferably be the average value of thickness at individual centers of the bonded bodies stuck to the polishing plate mentioned above.

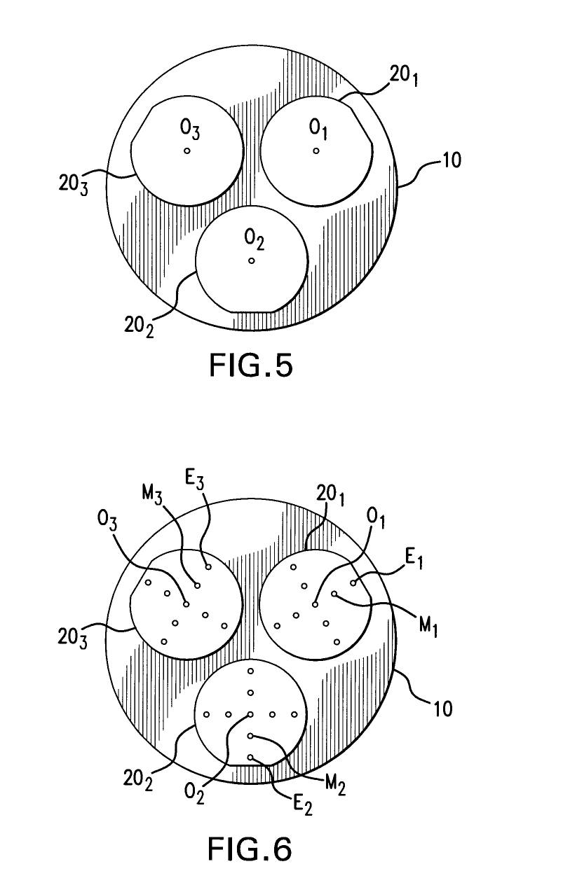

That is, in the case where three bonded bodies 20₁, 20₂, and 20₃ are stuck to the polishing plate 10 as shown in FIG. 5, the thickness of the active layer 20a is measured at individual centers O₁, O₂, and O₃ and an average value is calculated from the thus measured thickness. The resulting average value is defined as the second thickness.

The foregoing method is desirable because the active layer is easily made to have the thickness at the central point which conforms to the standard for all the bonded bodies stuck to the same polishing plate.

The second thickness to be measured by the foregoing step should more preferably be the average value of thickness at individual centers and many in-plane points including peripheral points of the bonded bodies stuck to the polishing plate mentioned above.

That is, in the case where three bonded bodies 20₁, 20₂, and 20₃ are stuck to the polishing plate 10 as shown in FIG. 6, the thickness of the active layer 20a is measured at individual centers O₁, O₂, and O₃ and also at in-plane points including peripheral points and an average value is calculated from the thus measured thickness. The resulting average value is defined as the second thickness. The in-plane points are indicated by M₁, M₂, and M₃ and the peripheral points are indicated by E₁, E₂, and E₃ which are 3 mm inside from the periphery of each of the bonded bodies 20₁, 20₂, and 20₃.

The foregoing method is desirable because the active layer is easily made to have the thickness at in-plane points which conforms to the standard for all the bonded bodies stuck to the same polishing plate.

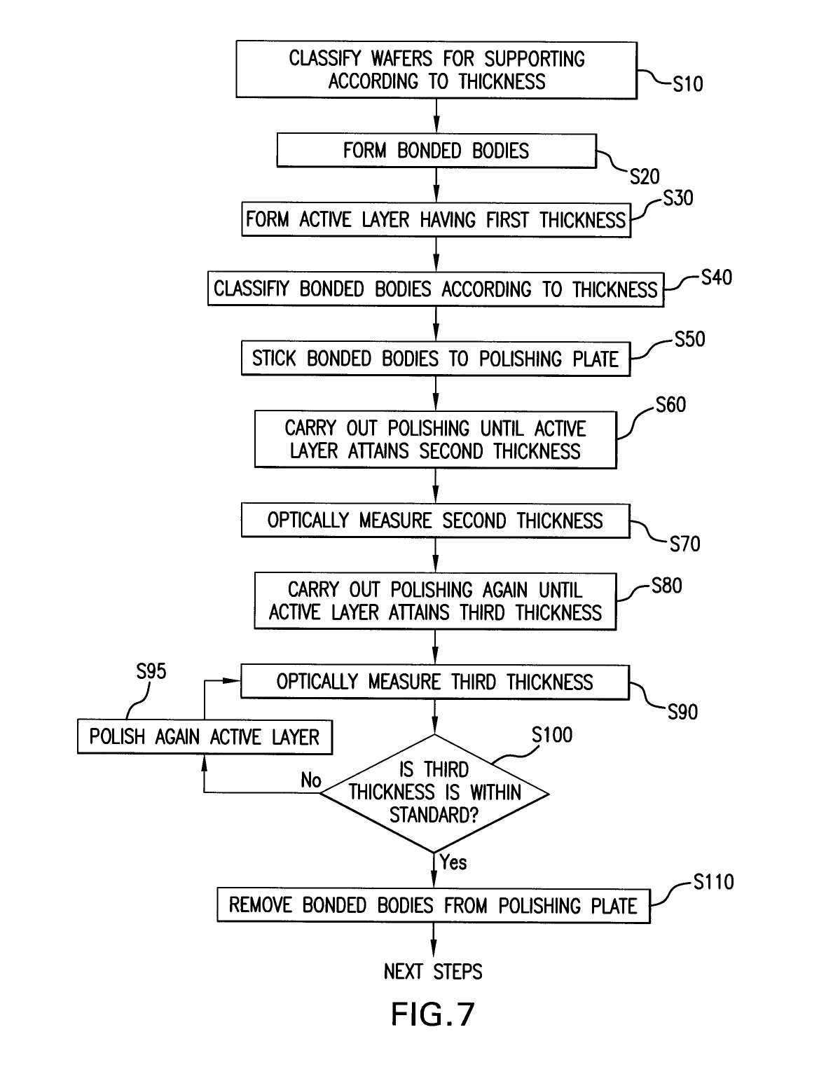

The following is a detailed description of the flow from the bonding step (S1) to the second polishing step (S5) mentioned above. FIG. 7 is a flowchart for production of bonded wafers according to the embodiment of the present invention.

The first step (S10) is to make ready wafers for supporting and wafers for the active layer. The wafers for supporting are those of single crystal silicon which have a diameter of 5 inches (125 mm) and a thickness of 600 to 800 μm, with their one side polished. The wafers for the active layer are those of single crystal silicon which have a diameter of 5 inches (125 mm) and a thickness of 600 to 800 μm, with their one side polished and also have a controlled oxygen concentration and resistance value. The wafers for supporting are classified according to their thickness.

Classification in S10 according to thickness should preferably be carried in such a way that the bonded bodies to be stuck to the same polishing plate in the subsequent polishing steps (S60, S80, and S90) have a variation in thickness which is within one half the tolerance of the thickness standard of the active layer of the wafer of the bonded body. For example, the variation should be within 0.5 μm if the thickness standard of the active layer is 5.0 to 7.0 μm (or 6.0 μm ±1.0 μm). The thickness for classification should preferably be measured at the center of the wafer for supporting.

The next step (S20) is to bond together the wafer for supporting (which has been classified) and the wafer for the active layer, thereby forming the bonded body. This step is identical with the bonding step (S1) mentioned above, and hence its explanation is omitted.

In the next step (S30), the bonded body is fabricated so that the active layer is thinned to a first thickness. This step is identical with the fabricating step (S2) mentioned above, and hence its explanation is omitted.

The next step (S40) is to classify the bonded bodies, with the active layer thereon having the first thickness, according to thickness.

Classification in S40 according to thickness should preferably be carried in such a way that the bonded bodies to be stuck to the same polishing plate in the subsequent polishing steps (S60, S80, and S90) have a variation in thickness which is within one half the tolerance of the thickness standard of the active layer of the wafer of the bonded body. For example, the variation should be within 0.5 μm if the thickness standard of the active layer is 5.0 to 7.0 μm (or 6.0 μm±1.0 μm). The thickness for classification should preferably be measured at the center of the bonded body.

In the next step (S50), the bonded bodies which have been classified according to thickness are stuck to the polishing plate. The bonded bodies to be stuck to the same polishing plate should be selected from those which have less than one half the tolerance of the standard in variation for the thickness of the wafer for supporting and the thickness of the bonded bodies. This selection should be made according to the results of thickness classification (in S10) for the wafers for supporting and thickness classification (in S40) for the bonded bodies. If the number of the bonded bodies to be stuck to the polishing plate is not just enough to fill the area of the polishing plate, the vacant area should be filled with dummy wafers which are selected such that the difference in thickness between the bonded bodies and the dummy wafers is within one half the tolerance of the standard. Such a case will occur if there are only one or two bonded bodies in the case shown in FIG. 3.

The classification by thickness (in S10 and S40) and the selection by thickness of the bonded bodies to be stuck to the polishing plate makes it easy to control the thickness of the active layer within the standard for all the bonded bodies stuck to the same polishing plate in the polishing steps (S60, S80, and S95) to be mentioned later. Their additional effect is reduction in variation in the in-plane thickness of the bonded bodies and the active layer after polishing in the polishing steps (S60, S80, and S95).

The next step (S60) is to polish the bonded bodies stuck to the polishing plate so that the active layer attains the second thickness. This step is identical with the first polishing step (S3) mentioned above, and hence its explanation is omitted.

The next step (S70) is to optically measure the second thickness, while keeping the bonded bodies stuck to the polishing plate after polishing. This step is identical with the measuring step (S4) mentioned above, and hence its explanation is omitted.

In the next step (S80), the active layer is polished again, in response to the second thickness measured in the previous step, until it attains the third thickness. This step is identical with the second polishing step (S5) mentioned above, and hence its explanation is omitted.

The next step (S90) is to optically measure the third thickness, while keeping the bonded bodies stuck to the polishing plate after polishing. This step is identical with the measuring step (S4) mentioned above, and hence its explanation is omitted.

The next step (S100) is to confirm that the third thickness measured previously is within the standard for the thickness of the active layer. If the third thickness is still thicker than the standard (or does not conform to the standard as indicated by No), the active layer is polished again in the step (S95). Such a case will occur when the polishing rate decreases due to clogging of polishing cloth. This step is identical with the second polishing step (S6) mentioned above, and hence its explanation is omitted.

If the third thickness after repolishing in S80 or S95 is within the standard for the thickness of the active layer (as indicated by Yes), polishing of the active layer is terminated and the bonded bodies are removed from the polishing plate in the next step (S110). The bonded bodies are transferred to the subsequent step for cleaning etc.

### Examples

The present invention will be described in more detail with reference to the following examples 1 to 3, which are not intended to restrict the scope of the invention.

A bonded wafer was prepared according to the flowchart shown in FIG. 7 under the following polishing conditions which are common to all the examples.
Wafer for supporting: silicon wafer, 5 inches (125 mm) in diameter and 625±25 μm in thickness
Wafer for the active layer: silicon wafer, 5 inches (125 mm) in diameter and 625±25 μm in thickness
The first thickness: 20 to 25 μm
The second thickness: 10 to 12 μm
The third thickness: 6.0±1.0 μm (conforming to the standard for the thickness of the active layer of the bonded wafer)

### Example 1

Before being stuck to the polishing plate, bonded wafers were sorted according to the thickness of the wafer for supporting and the thickness of the bonded wafers such that their variation is within one half the tolerance of the standard (or within 0.5 μm) for the thickness of the active layer of the bonded bodies. The thus sorted bonded bodies were stuck to the same polishing plate and polished until the third thickness is attained. Incidentally, in Example 1, the second thickness was measured at only one central point of one bonded body arbitrarily selected from the bonded bodies stuck to the polishing plate.

As the result, a 100% yield was achieved when 100 bonded bodies were fabricated such that the active layer has the thickness conforming to the standard.

### Comparative Example 1

The same procedure as in Example 1 was repeated to carry out polishing to attain the third thickness except that the bonded bodies were sorted such that the variation of the foregoing thickness is within 0.7 μm. As the result, the yield was 80% when 100 bonded bodies were fabricated such that the active layer has the thickness conforming to the standard.

### Comparative Example 2

The same procedure as in Example 1 was repeated to carry out polishing to attain the third thickness except that the bonded bodies were sorted such that the variation of the foregoing thickness is within 1.0 μm. As the result, the yield was 46% when 100 bonded bodies were fabricated such that the active layer has the thickness conforming to the standard.

### Example 2

The same procedure as in Example 1 was repeated to carry out polishing to attain the third thickness except that the second thickness was an average value of measurements at the central point of individual bonded bodies stuck to the polishing plate.

As the result, a 100% yield was achieved when 100 bonded bodies were fabricated such that the active layer has the thickness conforming to the standard. A 100% yield was also achieved even when the standard of thickness for the active layer of the bonded body was changed to 6.0±0.75 μm.

### Example 3

The same procedure as in Example 1 was repeated to carry out polishing to attain the third thickness except that the second thickness was an average value of measurements at the central point and the in-plane points including peripheral points (nine in-plane points shown in FIG. 6) of individual bonded bodies stuck to the polishing plate.

As the result, a 100% yield was achieved when 100 bonded bodies were fabricated such that the active layer has the thickness (including the one at in-plane nine points) conforming to the standard. A 100% yield was also achieved even when the standard of thickness for the active layer of the bonded body was changed to 6.0±0.75 μm.

What is claimed is:

1. A method for producing bonded wafers, comprising the steps of:
bonding together a wafer for supporting and a wafer for active layer, thereby forming bonded bodies;
fabricating the wafer for active layer of the bonded bodies, thereby forming the active layer having a first thickness;
sticking the bonded bodies having the active layer formed thereon to a polishing plate and polishing the active layer down to a second thickness;
optically measuring the second thickness while keeping the polished bonded bodies stuck to the polishing plate; and
polishing again the active layer down to a third thickness in response to the second thickness measured previously.

2. The method as defined in claim 1, wherein the second thickness to be measured is an average of measurements at the central point of individual bonded bodies stuck to the polishing plate.

3. The method as defined in claim 1, wherein the second thickness to be measured is an average of measurements at the central point and multiple in-plain points including peripheral points of individual bonded bodies stuck to the polishing plate.
